(19) United States
(12) Patent Application Publication
(10) Pub. No.: US 2024/0186970 A1
(43) Pub. Date: Jun. 6, 2024

(54) AMPLIFIER CIRCUIT AND PHOTODETECTION DEVICE

(71) Applicant: Kabushiki Kaisha Toshiba, Tokyo (JP)

(72) Inventors: Tetsuro ITAKURA, Nerima Tokyo (JP); Tuan Thanh TA, Kawasaki Kanagawa (JP); Toshiki SUGIMOTO, Kawasaki Kanagawa (JP)

(21) Appl. No.: 18/460,021

(22) Filed: Sep. 1, 2023

(30) Foreign Application Priority Data
Dec. 6, 2022 (JP) 2022-194994

(51) Int. Cl. H03F 3/45; H03F 1/08

(52) U.S. Cl. CPC H03F 3/45475; H03F 1/086; H03F 3/45273

(57) ABSTRACT

An amplifier circuit includes a plurality of gain stages that change a gain in each stage and include a first gain stage and a final gain stage, an output terminal that outputs a signal amplified by the plurality of gain stages, a negative input terminal connected to an input node of the first gain stage, a feedback circuit connected between an output node of the final gain stage and the negative input terminal, a first resistor connected between the output node of the final gain stage and the output terminal, an active load of the first gain stage including a first transistor, a second resistor connected to a gate or a base of the first transistor, and a capacitor connected between the gate or the base of the first transistor and the output node of the final gain stage.

### CROSS-REFERENCE TO RELATED APPLICATIONS

This application is based upon and claims the benefit of priority from the prior Japanese Patent Application No. 2022-194994, filed on Dec. 6, 2022, the entire contents of which are incorporated herein by reference.

### FIELD

An embodiment of the present invention relates to an amplifier circuit and a photodetection device.

### BACKGROUND

In an amplifier circuit such as an operational amplifier, a phase delay may occur at poles on a signal path, and in some cases, the phase delay may oscillate beyond 180 degrees. Therefore, a phase compensation capacitor may be added in order to shift the frequencies of the poles to a low frequency side and a high frequency side, respectively.

When a large capacitance load is connected to an amplifier circuit, it is necessary to enlarge a phase compensation capacitor, and downsizing is difficult. Therefore, an amplifier circuit has been proposed in which a small phase compensation capacitor is connected to a large capacitance load or an amplification operation is stably performed without using the phase compensation capacitor.

However, a technique of stably performing an amplification operation both on a small capacitance load and a large capacitance load has not been proposed actually.

### BRIEF DESCRIPTION OF THE DRAWINGS

FIG. 1 is a block diagram of an amplifier circuit according to a first embodiment;

FIG. 2A is a circuit diagram of the amplifier circuit according to the first embodiment;

FIG. 2B is a small signal equivalent circuit of the amplifier circuit according to the first embodiment;

FIG. 3A is a circuit diagram of an amplifier circuit according to a comparative example;

FIG. 3B is a small signal equivalent circuit of the amplifier circuit according to the comparative example;

FIG. 4 is a circuit diagram of an amplifier circuit according to a first modification of the first embodiment;

FIG. 5 is a circuit diagram of an amplifier circuit according to a second modification of the first embodiment;

FIG. 6A is a diagram illustrating an open loop frequency characteristic in the amplifier circuit according to the second modification of the first embodiment;

FIG. 6B is a diagram illustrating a transient analysis waveform when the amplifier circuit according to the second modification of the first embodiment has a voltage follower configuration;

FIG. 7 is a circuit diagram of an amplifier circuit according to a third modification of the first embodiment;

FIG. 8A is a diagram illustrating an open loop frequency characteristic in the amplifier circuit according to the third modification of the first embodiment;

FIG. 8B is a diagram illustrating a transient analysis waveform when the amplifier circuit according to the third modification of the first embodiment has a voltage follower configuration;

FIG. 9 is a circuit diagram of an amplifier circuit according to a fourth modification of the first embodiment; and

FIG. 10 is a block diagram of a photodetection device according to a second embodiment.

### DETAILED DESCRIPTION

In order to solve the above problem, an embodiment of the present invention provides an amplifier circuit including:
a plurality of gain stages that change a gain in each stage and include a first gain stage and a final gain stage;
an output terminal that outputs a signal amplified by the plurality of gain stages;
a negative input terminal connected to an input node of the first gain stage;
a feedback circuit connected between an output node of the final gain stage and the negative input terminal;
a first resistor connected between the output node of the final gain stage and the output terminal;
an active load of the first gain stage including a first transistor;
a second resistor connected to a gate or a base of the first transistor; and
a capacitor connected between the gate or the base of the first transistor and the output node of the final gain stage.

Hereinafter, embodiments of an amplifier circuit and a photodetection device will be described with reference to the drawings. Hereinafter, main components of the amplifier circuit and the photodetection device will be mainly described, but the amplifier circuit and the photodetection device may have components and functions that are not illustrated or described. The following description does not exclude components and functions that are not illustrated or described.

### FIRST EMBODIMENT

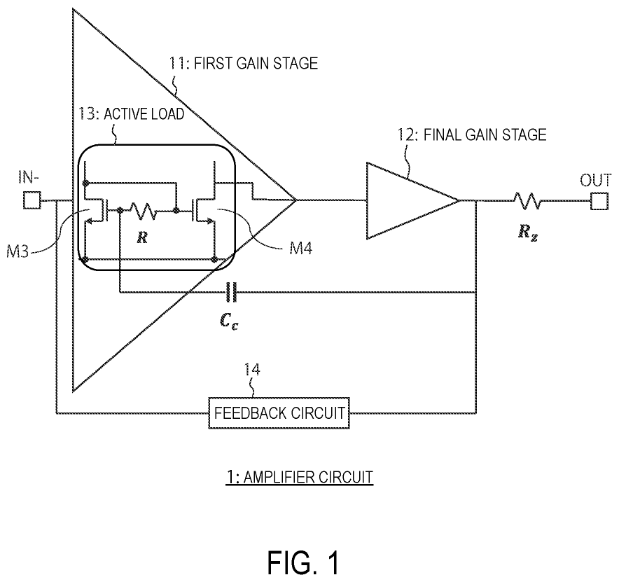

FIG. 1 is a block diagram of an amplifier circuit 1 according to a first embodiment. The amplifier circuit 1 of FIG. 1 includes a plurality of gain stages including a first gain stage 11 and a final gain stage 12, an output terminal OUT, a negative input terminal IN−, a first resistor R_{z}, an active load 13 of the first gain stage 11, a second resistor R, a capacitor C_{c}, and a feedback circuit 14.

The plurality of gain stages changes a gain in each stage and includes at least the first gain stage 11 and the final gain stage 12.

The output terminal OUT outputs a signal amplified by the plurality of gain stages. The negative input terminal IN− is connected to an input node of the first gain stage 11.

The first resistor R_{z} is connected between an output node of the final gain stage 12 and the output terminal OUT. By adding the first resistor R_{z}, as will be described later, an amplification operation can be stably performed regardless of the magnitude of a load capacitor connected to the output terminal OUT of the amplifier circuit 1. More specifically, by connecting the first resistor R_{z}, even when the load capacitor is small, a phase margin of the amplifier circuit 1 can be increased, and a stable amplification operation can be performed.

The active load 13 of the first gain stage 11 includes at least a first transistor. In the example of FIG. 1, the active load 13 includes transistors M3 and M4. The second resistor R is connected to a gate or a base of the first transistor (for example, the transistor M3).

The capacitor C_{c} is connected between the gate or the base of the first transistor and the output node of the final gain stage 12. The capacitor C_{c} functions as a phase compensation capacitor. In the amplifier circuit 1 of FIG. 1, a capacitance of the capacitor C_{c} can be decreased, and the amplifier circuit 1 can be downsized.

The feedback circuit 14 is connected between the output node of the final gain stage 12 and the negative input terminal IN−. The feedback circuit 14 may be formed only of wiring having no active element and no passive element. When the feedback circuit 14 simply has wiring, the amplifier circuit 1 of FIG. 1 functions as a voltage follower circuit.

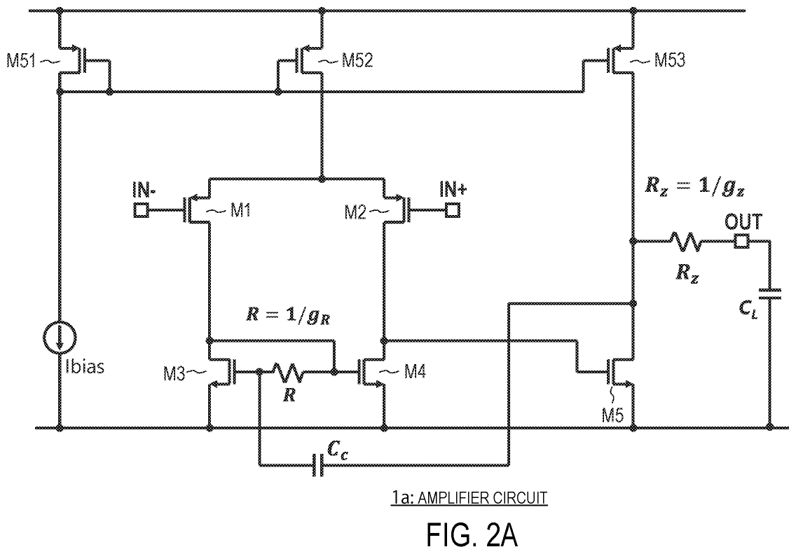

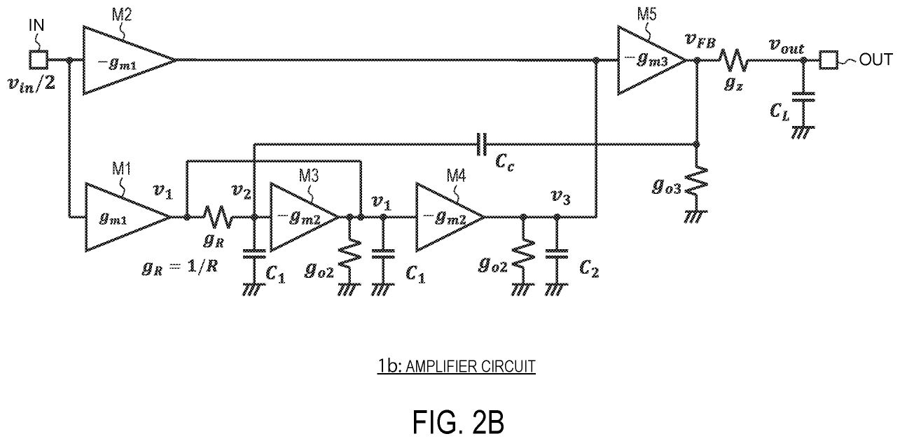

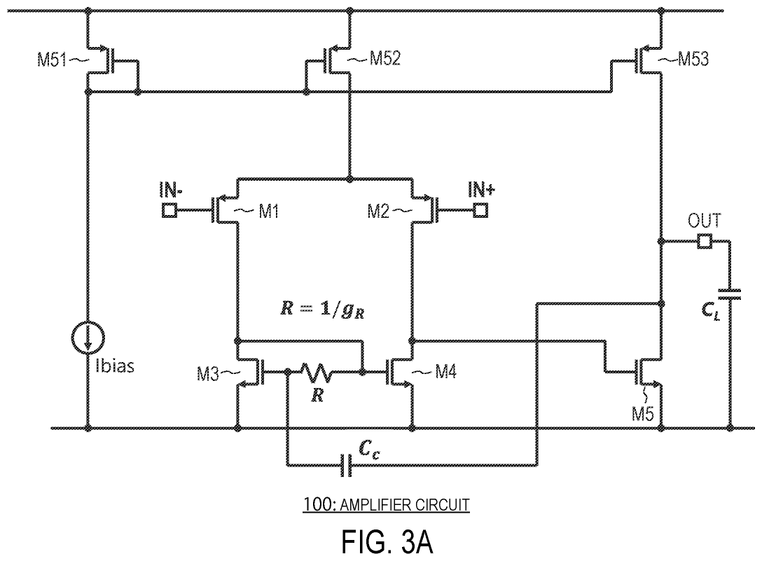

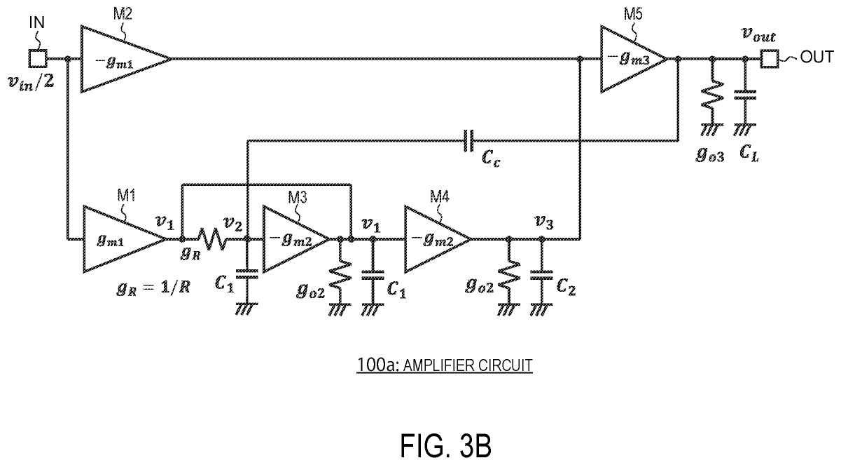

FIG. 2A is a circuit diagram of an amplifier circuit 1a according to the first embodiment, embodying FIG. 1, and FIG. 3A is a circuit diagram of an amplifier circuit 100 according to a comparative example. First, using the amplifier circuit 100 of the comparative example of FIG. 3A, it will be described that an amplification operation is unstable at the time of a small load capacitor.

The amplifier circuit 100 illustrated in FIG. 3A includes a bias circuit including a current source Ibias and transistors M51, M52, and M53, a differential amplifier circuit that is a first gain stage including transistors M1, M2, M3, and M4 to which a bias current is supplied from the transistor M52, a common-source amplifier circuit (or an common-emitter amplifier circuit) that is a final gain stage including the transistor M53 and a transistor M5 that supplies a bias current and operate as active loads, a resistor R (second resistor), and a capacitor C_{c}.

In the present specification, an example is illustrated in which the transistors M1, M2, and M51 to M53 are PMOS transistors, and the transistors M3 to M5 are NMOS transistors, but any conductivity type can be used for the transistors. In addition, these transistors may bipolar transistors.

Among the transistors M1 to M4 constituting the first gain stage, the transistors M3 and M4 are active loads of the first gain stage. The transistors M3 and M4 constitute a current mirror circuit. In the present specification, the transistor M3 may be referred to as a first transistor, and the transistor M4 may be referred to as a second transistor.

The resistor R is connected between a gate of the transistor M3 and a gate of the transistor M4. The capacitor C_{c} is connected between the gate of the transistor M3 and a drain of the transistor M5 that is an output node of the common-source amplifier circuit that is the final gain stage.

When a drain voltage of the transistor M5 increases, a current flows to the gate of the transistor M3 via the capacitor C_{c}, and a gate voltage of the transistor M3 increases. The current flowing to the gate of the transistor M3 flows to the resistor R, and a gate voltage of the transistor M4 decreases. When the gate voltage of the transistor M4 decreases, a gate voltage of the transistor M5 increases, and the drain voltage of the transistor M5 decreases. In this manner, the gate of the transistor M3 to which one end of the capacitor C_{c} is connected and the output node of the final gain stage (the drain of the transistor M5) have a reverse phase relationship.

That is, a gain from the gate of the transistor M3 to the output node of the final gain stage has a negative polarity when a DC signal is input.

Input terminals IN+ and IN− of the amplifier circuit 100 are connected to gates of the transistors M1 and M2 constituting the differential amplifier circuit (differential circuit), and an output terminal OUT of the amplifier circuit 100 is connected to the drain of the transistor M5 that is an output of the source-grounded amplifier circuit that is the final gain stage.

FIG. 3B is a small signal equivalent circuit of the amplifier circuit 100 according to the comparative example of FIG. 3A. In an amplifier circuit 100a illustrated in FIG. 3B, the transistors constituting the differential amplifier circuit and the common-source amplifier circuit are represented by a transconductor, an output resistor, and a parasitic capacitor. In FIG. 3B, the parallel output resistors of the plurality of transistors are integrated. The input terminals IN+ and IN− of the amplifier circuit 100 are integrated into an input terminal IN.

In FIG. 3B, the output resistors and the resistor R in the amplifier circuit 100 of FIG. 3A are represented by conductance values that are reciprocals of resistance values. More specifically, in FIG. 3B, the transconductance values of the transistors M1, M2, M3, M4, and M5 and the conductance of the resistor R are represented by gₘ₁, −gₘ₁, −gₘ₂, −gₘ₂, −gₘ₃, and g_{R}, respectively. The output conductance values of M1 and M3 are integrated to gₒ₂, and the output conductance values of M2 and M4 are integrated to gₒ₂, respectively. The output conductance values of M5 and M53 are integrated to gₒ₃.

In the equivalent circuit illustrated in FIG. 3B, the capacitor C_{c} and a parasitic capacitor C₁ are connected to the conductance g_{R} corresponding to the resistor R and the gate of the transistor M3. A conductance gₒ₂ is connected to an output node corresponding to a drain of the transistor M3. The parasitic capacitor C₁ of the transistor M3 is connected between an output node corresponding to drains of the transistors M1 and M3 and an input node corresponding to a gate of the transistor M4. The conductance gₒ₂ and a parasitic capacitor C₂ are connected between an output node corresponding to a drain of the transistor M4 and a gate of the transistor M5 that is an input node of the final gain stage. A conductance gₒ₃ is connected to a drain of the transistor M5 that is an output node of the final gain stage.

In FIG. 3B, a voltage of an input node corresponding to gates of the transistors M1 and M2 is represented as vᵢₙ/2, a voltage of an output node corresponding to a drain of the transistor M1 is represented as v1, a voltage of an input node corresponding to a gate of the transistor M3 is represented by v2, a voltage of an output node corresponding to a drain of the transistor M4 is represented by v3, and a voltage of an output node of the amplifier circuit 100a is represented by vₒᵤₜ.

vₒᵤₜ/vᵢₙ is obtained using the equivalent circuit illustrated in FIG. 3B, and frequencies of poles are approximately obtained from a denominator polynomial of vₒᵤₜ/vᵢₙ. The amplifier circuit 100 of FIG. 3A has three poles in which a phase delay occurs. In this specification, the three poles are referred to as a first pole, a second pole, and a third pole from a low frequency side toward a high frequency side. A first pole frequency p₁ is obtained by the following formula (1) .

$$\begin{matrix}[ Numerical Formula 1 ] & \\ {p}_{1} \approx - \frac{{g}_{o 2} {g}_{o 3} {g}_{R}}{{C}_{c} {g}_{m 2} {g}_{m 3} + {C}_{L} {g}_{o 2} {g}_{R}} & ( 1 )\end{matrix}$$

The second and third poles have a complex conjugate relationship, and a frequency ω₀ thereof and a Q value thereof are obtained by the following formulas (2) and (3). The Q value is a numerical value indicating a degree of change in gain with respect to a frequency change, and it is indicated that the gain more rapidly changes as the Q value is larger. When the Q value is large, a stable amplification operation is difficult.

$$\begin{matrix}[ Numerical Formula 2 ] & \\ {ω}_{o} = \sqrt{\frac{{g}_{m 2} ( {C}_{c} {g}_{m 2} {g}_{m 3} + {C}_{L} {g}_{o 2} {g}_{R} )}{{C}_{2} {C}_{c} {C}_{L} {g}_{R}}} & ( 2 )\end{matrix}$$

$$Q \approx \sqrt{\frac{{g}_{m 2} ( {C}_{c} {g}_{m 2} {g}_{m 3} + {C}_{L} {g}_{o 2} {g}_{R} ) {C}_{2}}{{C}_{c} {C}_{L} {g}_{R} {{g}_{o 2}}^{2}}} \qquad ( 3 )$$

Here, when the load capacitor C_{L} is small, approximation is further performed as follows.

$$\begin{matrix}[ Numerical Formula 3 ] & \\ {p}_{1} \approx - \frac{{g}_{o 2} {g}_{o 3} {g}_{R}}{{C}_{c} {g}_{m 2} {g}_{m 3}} & ( 4 )\end{matrix}$$

$${ω}_{o} = \sqrt{\frac{{g}_{m 2} {g}_{m 2} {g}_{m 3}}{{C}_{2} {C}_{L} {g}_{R}}} \qquad ( 5 )$$

$$Q \approx \sqrt{\frac{{g}_{m 2} {g}_{m 2} {g}_{m 3} {C}_{2}}{{C}_{L} {g}_{R} {{g}_{o 2}}^{2}}} \qquad ( 6 )$$

In general, gₘ₂/gₒ₂ is about 100.The parasitic capacitor C₂ is about 100 fF, and when the load capacitor C_{L} is about 5 pF, C₂/CL_{L} is 1/50.

In order to decrease the first pole frequency p₁, it is necessary to set the resistor R such that gₘ₃/g_{R} is 10. For example, in generally used Miller compensation, the first pole frequency p₁ is −gₒ₂gₒ₃/(gₘ₃Cₘ) , where Cₘ is the compensation capacitor for Miller compensation. Therefore, gₘ₂/g_{R} is set to about 10 in order to achieve the same first pole frequency p₁ with a smaller capacitor C_{c} (for example, about 1/10 of the compensation capacitor Cₘ) . Here, since gₘ₂ and gₘ₃ substantially coincide with each other, it is necessary to set the resistor R such that gₘ₃/g_{R} is 10.

In addition, gₘ₂/g_{R}=gₘ₂R is about 10. As described above, a product of the transconductance value of the transistor M3 and the resistance value of the resistor R is desirably at least one or more.

When the resistor R is set as described above, the Q value is obtained to be about 44. When the Q value is high, the phase is rapidly delayed at the frequency ωₒ. For this reason, when the load capacitor C_{L} is small, a phase margin of the amplifier circuit 100a cannot be obtained, and the amplifier circuit 100a is unstable.

The amplifier circuit 1a according to the first embodiment illustrated in FIG. 2A includes the resistor R_{z} (first resistor) in addition to the components of the amplifier circuit 100 illustrated in FIG. 3A. The resistor R_{z} is connected between a drain of the transistor M5 that is an output node of the source-grounded amplifier circuit and the output terminal OUT of the amplifier circuit 1a.

Note that, as illustrated in FIG. 1, the amplifier circuit 1a of FIG. 2A actually includes a feedback circuit connected between the negative input terminal IN− and the drain of the transistor M5 that is an output of the common-source amplifier circuit that is the final gain stage.

In phase compensation using the resistor R and the capacitor C_{c}, the resistor R_{z} can introduce a zero point together with the load capacitor C_{L}. In addition, the resistor R_{z} has an effect of decreasing Q values of higher-order poles having the above-described complex conjugate relationship. Hereinafter, description will be made.

FIG. 2B is a small signal equivalent circuit of the amplifier circuit 1a of FIG. 2A. In an amplifier circuit 1b illustrated in FIG. 2B, as in FIG. 3B, the resistor R_{z} is represented by a conductance g_{z} that is a reciprocal of the resistor R_{z}. A conductance gₒ₃ corresponding to an output resistor is connected between an output node corresponding to a drain of the transistor M5 and the conductance g_{z} corresponding to the resistor R_{z}.

In order to examine stability of the amplifier circuit 1a of FIG. 2A using the equivalent circuit illustrated in FIG. 2B, it is only required to obtain a transfer function v_{FB}/vᵢₙ from an input voltage vᵢₙ input to a negative input terminal to a drain voltage v_{FB} of the transistor M5 that is an output node of the final gain stage. Frequencies p₁, p₂, p₃, and p₄ of the first to fourth poles are approximately obtained from a denominator polynomial of the transfer function v_{FB}/vᵢₙ.

The first pole frequency p₁, the second pole frequency p₂, and a frequency ω₀ of the third and fourth poles having a complex conjugate relationship are obtained by the following formulas (7) and (8) .

$$\begin{matrix}[ Numerical Formula 4 ] & \\ {p}_{1} \approx - \frac{{g}_{o 2} {g}_{o 3} {g}_{R}}{{C}_{c} {g}_{m 2} {g}_{m 3} + {C}_{L} {g}_{o 2} {g}_{R}} & ( 7 )\end{matrix}$$

$${p}_{2} \approx - \frac{{g}_{2} ( {C}_{c} {g}_{m 2} {g}_{m 3} + {C}_{L} {g}_{o 2} {g}_{R} )}{{C}_{L} ( {C}_{c} {g}_{m 2} {g}_{m 3} + {C}_{2} {g}_{R} {g}_{2} )} \qquad ( 8 )$$

$${ω}_{o} = \sqrt{\frac{{g}_{m 2} ( {C}_{c} {g}_{m 2} {g}_{m 3} + {C}_{2} {g}_{R} {g}_{2} )}{{C}_{1} {C}_{2} {C}_{c} {g}_{R}}} \approx \sqrt{\frac{{g}_{m 2} {g}_{m 2} {g}_{m 3}}{{C}_{1} {C}_{2} {g}_{R}}} \qquad ( 9 )$$

Q values of the third and fourth poles are obtained by the following formula (10).

$$\begin{matrix}[ Numerical Formula 5 ] & \\ Q \approx \sqrt{\frac{{g}_{m 2} ( {C}_{c} {g}_{m 2} {g}_{m 3} + {C}_{2} {g}_{R} {g}_{z} ) {C}_{1} {C}_{c}}{{C}_{2} {{C}_{L}}^{2} {g}_{z} {{g}_{R}}^{2}}} \approx \sqrt{\frac{{g}_{m 2} {g}_{m 2} {g}_{m 3} {C}_{1} {{C}_{c}}^{2}}{{C}_{2} {{C}_{L}}^{2} {g}_{z} {{g}_{R}}^{2}}} & ( 10 )\end{matrix}$$

A frequency z₁ at a first zero and a frequency z₂ at a second zero are approximated as indicated in the following formulas (11) and (12) .

$$\begin{matrix}[ Numerical Formula 6 ] & \\ {z}_{1} \approx - \frac{2 {g}_{R}}{{C}_{c}} & ( 11 )\end{matrix}$$

$${z}_{2} \approx - \frac{{g}_{z}}{{C}_{L}} \qquad ( 12 )$$

Here, when the load capacitor C_{L} is small, the first pole frequency p₁ and the second pole frequency p₂ are further approximated as indicated in the following formulas (13) and (14).

$$\begin{matrix}[ Numerical Formula 7 ] & \\ {p}_{1} \approx - \frac{{g}_{o 2} {g}_{o 3} {g}_{R}}{{C}_{c} {g}_{m 2} {g}_{m 3}} & ( 13 )\end{matrix}$$

$${p}_{2} \approx - \frac{{g}_{z}}{{C}_{L}} \qquad ( 14 )$$

When the load capacitor C_{L} is small, the first pole frequency p₁ is the same as a first pole frequency p₁ obtained by a conventional method illustrated in formula (4) , as obtained by formula (13). The second pole frequency p₂ is approximately equal to the second zero frequency z₂ and is canceled. Therefore, the third and fourth poles affect a phase after the first poles.

Regarding Q values of the third and fourth poles having a complex conjugate relationship, the parasitic capacitors C₁ and C₂ are in almost the same order and can be approximated to be C₁=C₂, C_{C}/C_{L} is about 1/10, and g_{z/}gₘ₃ is about 1/10. In addition, similarly to the above, when gₘ₃/g_{R} is about 10, Q is about √(1/10) and is about 0.3, and therefore the Q values can be decreased. Here, gₘ₂ and gₘ₃ almost coincide with each other, gₘ₃/g_{R}=10

Furthermore, regarding the frequency ω₀ of the third and fourth poles, the load capacitor C_{L} is generally larger than the parasitic capacitor C₁ that is attached to an output node of the first gain stage as compared with the amplifier circuit 100 of FIG. 3A (comparison between formulas (5) and (9)) . Therefore, the pole frequency ω₀ that affects a phase can be increased to √(C_{L}/C₁) times.

As described above, the amplifier circuit 1a according to the first embodiment can further increase the higher-order pole frequency ω₀ that affects a phase without changing the first pole frequency p₁, as compared with the amplifier circuit 100 according to the comparative example of FIG. 3A. In addition, since the Q value indicating a degree of change in gain with respect to a frequency change can be decreased, a sufficient phase margin can be ensured even when the load capacitor C_{L} is small. That is, the amplifier circuit 1a according to the first embodiment can stably perform an amplification operation regardless of the load capacitor C_{L}.

A switching circuit that performs selection for connecting any one of a plurality of load circuits may be connected to an output node of the final gain stage of the amplifier circuit 1a illustrated in FIG. 2A. The switching circuit can be constituted using a transistor that switches between on and off, and an on-resistor of the transistor can be used as at least a part of the resistor R_{z}.

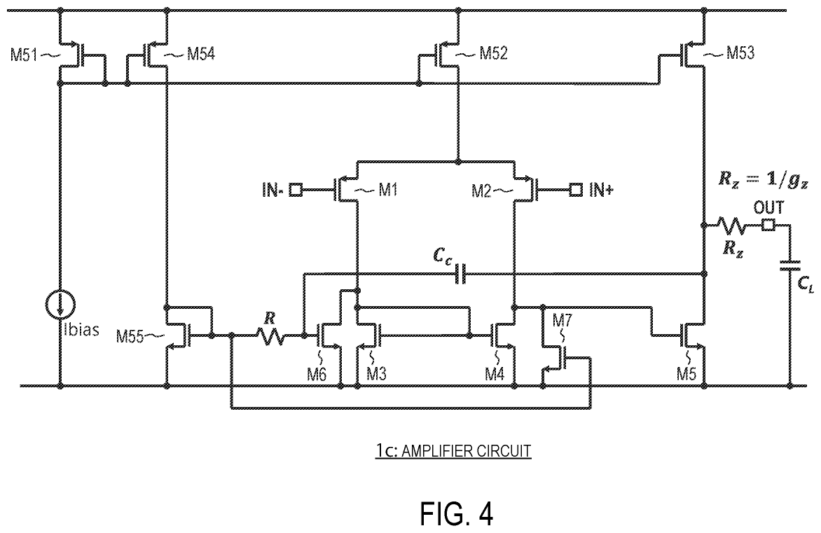

FIG. 4 is a circuit diagram of an amplifier circuit 1c according to a first modification of the first embodiment. The amplifier circuit 1c illustrated in FIG. 4 further includes transistors M6 and M7. In addition, a bias circuit of the amplifier circuit 1c further includes transistors M54 and M55. The transistor M54 is, for example, a PMOS transistor, and the transistors M6, M7, and M55 are, for example, NMOS transistors.

Drains of the transistors M6 and M7 are connected to drains of the transistors M3 and M4, respectively. The resistor R in the amplifier circuit 1c is connected between a gate of the transistor M6 and a gate of the transistor M7. The capacitor C_{c} in the amplifier circuit 1c is connected between a gate of the transistor M6 and a drain of the transistor M5.

A bias voltage generated by the transistor M55 is supplied to the gate of the transistor M6 via the resistor R. A bias voltage generated by the transistor M55 is directly supplied to the gate of the transistor M7. The gate of the transistor M6 to which the capacitor C_{c} is connected and the output node of the final gain stage (the drain of the transistor M5) have a reverse phase relationship. As described above, even if the transistor M6 is used for phase compensation instead of the transistor M3 constituting an active load in the differential amplifier circuit, a similar effect to that of the amplifier circuit 1a of FIG. 2A can be obtained.

The first pole frequency p₁ at this time is expressed as follows.

$$\begin{matrix}[ Numerical Formula 8 ] & \\ {p}_{1} \approx - \frac{{g}_{o 2} {g}_{o 3} {g}_{R}}{{C}_{c} {g}_{m 3} {g}_{m 4}} & ( 15 )\end{matrix}$$

Here, gₘ₄ is a transconductance value of the transistor M6. As described above, it is only required to determine a value of the resistor R such that gₘ₄/g_{R} is about 10.

Note that the transistor M7 keeps a balance by applying the same current as a bias current flowing by the transistor M6 to the transistor M4 side. The transistor M7 may be omitted, and the size of the transistor M4 may be adjusted.

In FIG. 4, the transistor M6 corresponds to the first transistor. In addition, as described above, one end of the resistor R is connected to the gate of the transistor M6, and a predetermined bias voltage is supplied to the other end of the resistor R via the transistor M55.

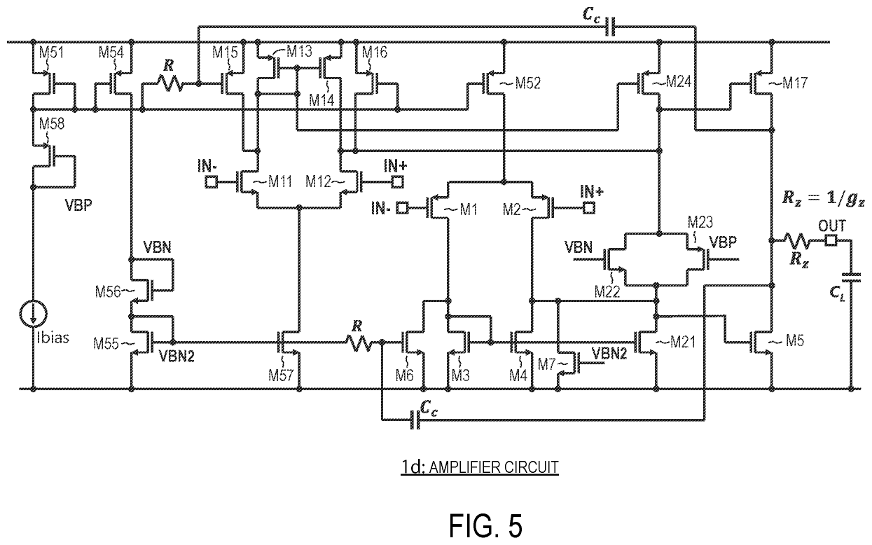

FIG. 5 is a circuit diagram of an amplifier circuit 1d according to a second modification of the first embodiment, and includes a circuit configuration in which the circuit configuration of the amplifier circuit 1c illustrated in FIG. 4 is partially changed. The amplifier circuit 1d illustrated in FIG. 5 includes a differential amplifier circuit including transistors M11 to M16 and M57 in order to expand a common-mode input voltage range, and a bias circuit for a class AB output including transistors M21 to M24.

Transistors M56 and M58 are further added in a bias circuit of the amplifier circuit 1d in order to generate the bias voltages VBN and VBP which are applied to the gates of M22 and M23, respectively. A transistor M17 forms another common-source amplifier circuit of the amplifier circuit 1d.

The transistors M13, M14, M15, M16, M17, M23, M24, and M58 are, for example, PMOS transistors, and the transistors M11, M12, M21, M22, M56, and M57 are, for example, NMOS transistors.

Each of the transistors M11 to M16 and M57 has a circuit configuration symmetrical to each of the transistors M1 to M4, M6, M7, and M52. Two Resistors R are connected to the gate of the transistor M6 and the gate of the transistor M15, respectively. Resistance values of these two resistors R are, for example, the same. A capacitor C_{c} is connected between the gate of the transistor M6 and a drain of the transistor M17 that is an output node of the final gain stage, and a capacitor C_{c} is connected between the gate of the transistor M15 and the drain of the transistor M17 that is the output node of the final gain stage. Capacitance values of these two capacitors C_{c} are, for example, the same. Note that the resistor R and the capacitor C_{c} connected to the gate of the transistor M6 may have different values from the resistor R and the capacitor C_{c} connected to the gate of the transistor M15.

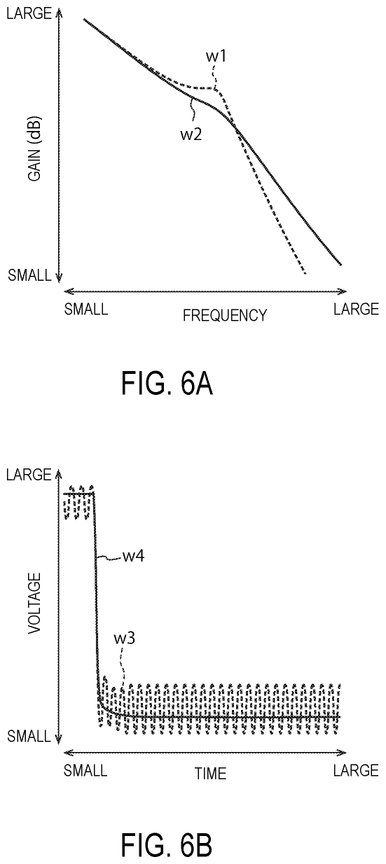

FIGS. 6A and 6B are diagrams illustrating simulation results for confirming an effect of the resistor R_{z} in the amplifier circuit 1d illustrated in FIG. 5. FIG. 6A is a diagram illustrating an open loop frequency characteristic. FIG. 6B is a diagram illustrating a transient analysis waveform when the feedback circuit simply has wiring to form a voltage follower configuration. FIGS. 6A and 6B each illustrate an example in which simulation is performed for a case where there is no resistor R_{z} and a case where there is the resistor R_{z} in the amplifier circuit 1d illustrated in FIG. 5. In FIG. 6A, the horizontal axis represents a frequency, the vertical axis represents a gain [dB], a waveform w1 represents a case where there is no resistor Rz, and a waveform w2 represents a case where there is the resistor Rz. In FIG. 6B, the horizontal axis represents time, the vertical axis represents voltage, a waveform w3 represents a case where there is no resistor Rz, and a waveform w4 represents a case where there is the resistor Rz.

In FIG. 6A, when there is no resistor R_{z}, a Q value of higher-order poles is high and there is no phase margin. Meanwhile, by adding the resistor R_{z}, the Q value of the higher-order poles decreases, and a phase margin can be ensured.

In FIG. 6B, when there is no resistor R_{z}, oscillation occurs before and after a signal falls. Meanwhile, by adding the resistor R_{z}, oscillation does not occur before and after a signal falls, and a stable amplification operation can be performed.

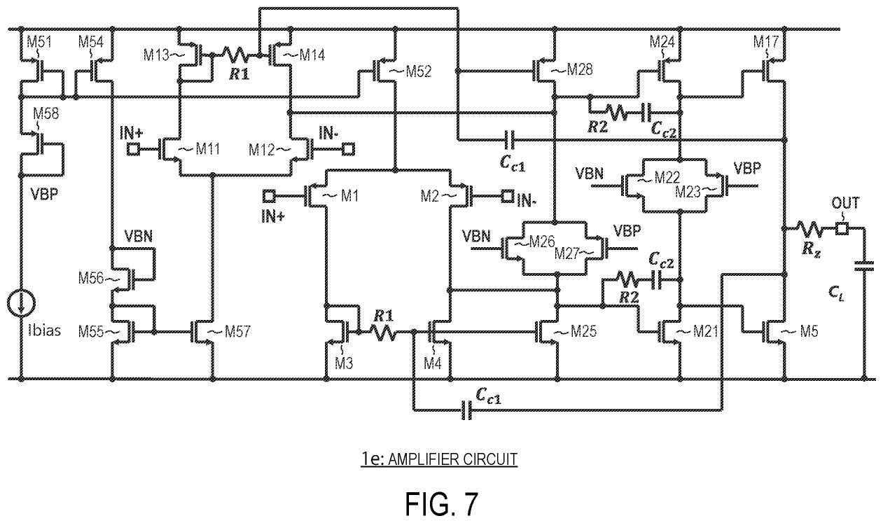

FIG. 7 is a circuit diagram of an amplifier circuit 1e according to a third modification of the first embodiment, and includes a circuit configuration in which the circuit configuration of the amplifier circuit 1d illustrated in FIG. 5 is partially changed. FIG. 7 illustrates an example in which the amplifier circuit has three gain stages. The amplifier circuit 1e illustrated in FIG. 7 has a configuration expanding a common-mode input voltage range, and includes a final gain stage constituted by a class AB common-source amplifier circuit.

A differential amplifier circuit including the transistors M1, M2, M3, and M4 to which a bias current is supplied from the transistor M52 and a differential amplifier circuit including the transistors M11, M12, M13, and M14 to which a bias current is supplied from the transistor M57 constitute a first gain stage.

The transistors M25 to M28 form a bias circuit that sets a bias voltage of a second gain stage. The transistors M21 and M24 form a common-source amplifier circuit constituting the second gain stage. The transistors M22 and M23 form a bias circuit that set a bias of the class AB common-source amplifier circuit constituting the final gain stage.

The transistors M27 and M28 are, for example, PMOS transistors, and the transistors M25 and M26 are, for example, NMOS transistors.

The amplifier circuit 1e is stabilized using capacitors C_{C1} and C_{C2}. Two capacitors C_{C1} and two capacitors C_{C2} are used.

The first gain stage of FIG. 7 includes two differential amplifier circuits (hereinafter, a first differential amplifier circuit and a second differential amplifier circuit) having symmetrical circuit configurations. The first differential amplifier circuit includes the transistors M1 to M4 and M52. The second differential amplifier circuit includes the transistors M11 to M14 and M57. The transistors M3 and M4 constitute an active load of the first differential amplifier circuit. The transistors M13 and M14 constitute an active load of the second differential amplifier circuit.

A resistor R1 is connected between a gate of the transistor M3 and a gate of the transistor M4. Similarly, a resistor R1 is connected between a gate of the transistor M13 and a gate of the transistor M14. A capacitor (first capacitor) C_{C1} is connected between the gate of the transistor M4 and a drain of the transistor M17 that is an output node of the final gain stage. A capacitor (second capacitor) C_{C1} is connected between the gate of the transistor M14 and a drain of the transistor M17 that is the output node of the final gain stage.

In the first differential amplifier circuit, an input terminal (negative input terminal) IN− is connected to a gate of the transistor M2, and an input terminal (positive input terminal) IN+ is connected to a gate of the transistor M1. To the input terminal IN+, a signal having a phase opposite to that of a signal input to the input terminal IN− is input. Similarly, in the second differential amplifier circuit, an input terminal IN− is connected to a gate of the transistor M12, and an input terminal IN+ is connected to a gate of the transistor M11.

A resistor (third resistor) R2 and a capacitor (third capacitor) C_{C2} are connected in series between a gate of the transistor M21 that is an input node of the second gain stage and a drain of the transistor M21 in FIG. 7. Similarly, a resistor (fourth resistor) R2 and a capacitor (fourth capacitor) C_{C2} are connected in series between a gate of the transistor M24 that is an input node of the second gain stage and a drain of the transistor M24.

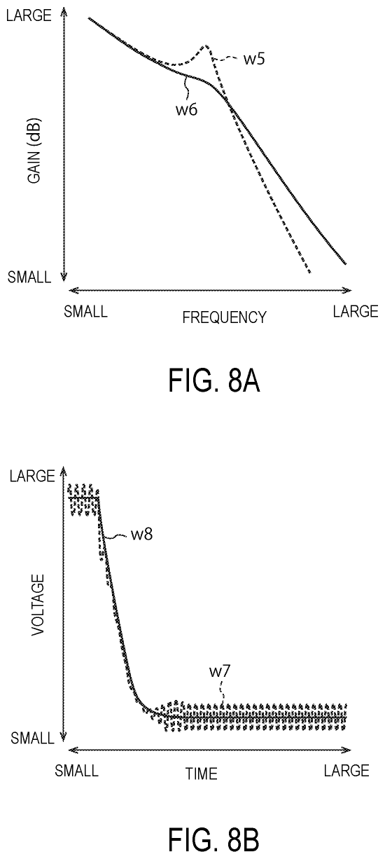

FIGS. 8A and 8B are diagrams illustrating simulation results for confirming an effect of the resistor R_{z} in the amplifier circuit 1e illustrated in FIG. 7. FIG. 8A is a diagram illustrating an open loop frequency characteristic. FIG. 8B is a diagram illustrating a transient analysis waveform when the feedback circuit simply has wiring to form a voltage follower configuration. FIGS. 8A and 8B each illustrate an example in which simulation is performed for a case where there is no resistor R_{z} and a case where there is the resistor R_{z} in the amplifier circuit 1e illustrated in FIG. 7. In FIG. 8A, the horizontal axis represents a frequency, the vertical axis represents a gain [dB], a waveform w5 represents a case where there is no resistor Rz, and a waveform w6 represents a case where there is the resistor Rz. In FIG. 8B, the horizontal axis represents time, the vertical axis represents voltage, a waveform w7 represents a case where there is no resistor Rz, and a waveform w8 represents a case where there is the resistor Rz.

In FIG. 8A, when there is no resistor R_{z}, a Q value of higher-order poles is high and there is no phase margin. Meanwhile, by adding the resistor R_{z}, the Q value of the higher-order poles decreases, and a phase margin can be ensured.

In FIG. 8B, when there is no resistor R_{z}, oscillation occurs before and after a signal falls in transient analysis. Meanwhile, by adding the resistor R_{z}, no oscillation occurs before and after a signal falls in transient analysis.

In each of the amplifier circuits 1, 1a, 1b, 1c, 1d, and 1e illustrated in FIGS. 1, 2A, 2B, 4, 5, and 7 described above, the capacitor C_{c} is connected between the active load of the first gain stage and the output node of the final gain stage, but one end of the capacitor C_{c} does not necessarily need to be connected to the active load of the first gain stage.

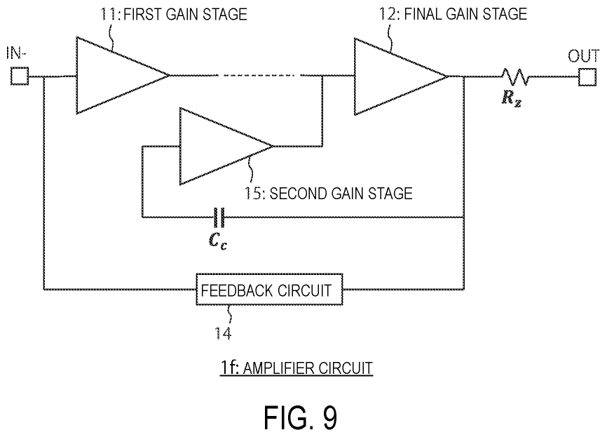

FIG. 9 is a block diagram illustrating a schematic configuration of an amplifier circuit 1f according to a fourth modification of the first embodiment. The amplifier circuit 1f of FIG. 9 includes a plurality of gain stages including a first gain stage 11, a second gain stage 15 and a final gain stage 12, an output terminal OUT, a negative input terminal IN−, a first resistor R_{z}, a capacitor C_{c}, and a feedback circuit 14.

The feedback circuit 14 is connected between an output node of the final gain stage 12 and an input node of the first gain stage 11. A first resistor R_{z} is connected between the output node of the final gain stage 12 and an output node of the amplifier circuit 1f. The capacitor C_{c} and the second gain stage 15 are connected in series to a path from the output node of the final gain stage 12 to an input node of the final gain stage 12.

Note that the second gain stage 15 includes a common-source amplifier circuit or a common-emitter amplifier circuit as in FIG. 7. In addition, a gain of the second gain stage 15 is larger than 1.

Also in the amplifier circuit 1f of FIG. 9, since the first resistor R_{z} is connected between the output node of the final gain stage 12 and the output terminal OUT, the Q value can be decreased, and a stable amplification operation can be performed even when a load capacitor is small.

An output node of the second gain stage 15 in the amplifier circuit 1f of FIG. 9 is connected to the input node of the final gain stage 12, but may be connected to an input node of a gain stage other than the final gain stage 12.

As described above, in the first embodiment, not only the capacitor C_{c} is used, but also the resistor R_{z} is connected between the output node of the final gain stage (the drain of the transistor M5) and the output terminal OUT, and therefore the Q value can be decreased, a phase margin can be ensured even when the load capacitor C_{L} is small, oscillation does not occur even when a signal steeply changes, and a stable amplification operation can be performed.

### SECOND EMBODIMENT

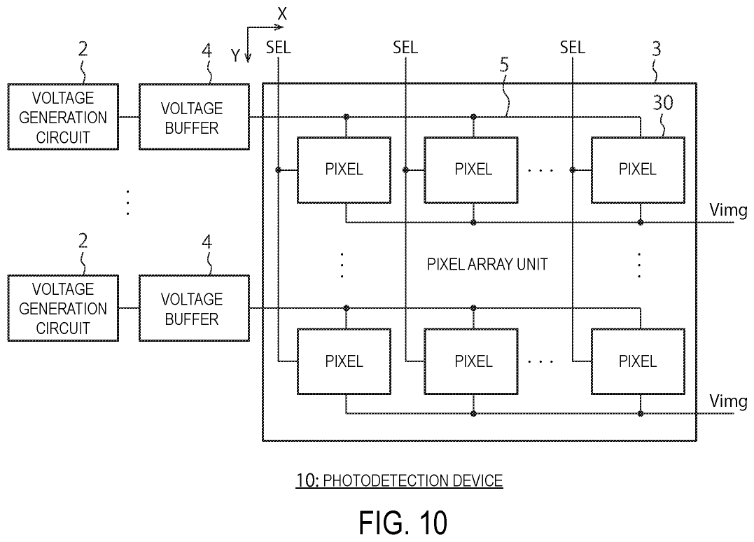

The amplifier circuit 1 (or the amplifier circuits 1a, 1b, 1c, 1d, 1e, or 1f) of the first embodiment can be built in a photodetection device that detects an optical signal. FIG. 10 is a block diagram of a photodetection device including an amplifier circuit according to a second embodiment.

The photodetection device 10 of FIG. 10 includes a voltage generation circuit 2, a pixel array unit 3, and a voltage buffer 4. The pixel array unit 3 includes a plurality of pixels 30 arrayed in each of a first direction X and a second direction Y.

Each of the plurality of pixels 30 includes a photoelectric conversion element that converts an optical signal into an electrical signal. A selection signal SEL is supplied from a drive circuit (not illustrated) to each of the pixels 30. Each of the pixels 30 outputs a pixel signal Vimg corresponding to an electrical signal generated by the photoelectric conversion element.

The voltage generation circuit 2 generates a predetermined bias voltage and supplies the generated bias voltage to the voltage buffer 4. The voltage buffer 4 includes the amplifier circuit 1, 1a, 1b, 1c, 1d, 1e, or 1f (hereinafter, collectively referred to as the amplifier circuit 1) according to the first embodiment.

The voltage buffer 4 in FIG. 10 is used for each pixel group including the plurality of pixels 30 arranged, for example, in the first direction X. A plurality of voltage generation circuits 2 and a plurality of voltage buffers 4 are arranged in the second direction Y in accordance with the number of pixel groups arrayed in the second direction Y. Each of the voltage buffers 4 supplies a bias voltage to each of the pixels 30 belonging to a corresponding pixel group via wiring 5.

As described above, since it is necessary to use the plurality of voltage buffers 4 in accordance with the number of pixel groups in the second direction Y, it is necessary to decrease the area of the voltage buffers 4 in order to integrate the photodetection device 10.

The amplifier circuit 1 is used as, for example, the voltage buffer 4 having a voltage follower configuration. The voltage buffer 4 drives an input impedance of the selected pixel 30 and a parasitic capacitor attached to the wiring 5 that extends to each of the pixels 30. In particular, the parasitic capacitor attached to the wiring 5 changes according to the number of pixel circuits in the first direction X.

The voltage buffer 4 of FIG. 10 can generate a bias voltage at a stable voltage level regardless of the magnitude of the number of pixels 30 arrayed in the first direction X in the pixel array unit 3. In addition, the voltage buffer 4 can be downsized. As a result, downsizing and a decrease in power consumption of the photodetection device can be achieved.

The above-described embodiments may be configured as follows.
(1) An amplifier circuit comprising:
   a plurality of gain stages that change a gain in each stage and include a first gain stage and a final gain stage;
   an output terminal that outputs a signal amplified by the plurality of gain stages;
   a negative input terminal connected to an input node of the first gain stage;
   a feedback circuit connected between an output node of the final gain stage and the negative input terminal;
   a first resistor connected between the output node of the final gain stage and the output terminal;
   an active load of the first gain stage including a first transistor;
   a second resistor connected to a gate or a base of the first transistor; and
   a capacitor connected between the gate or the base of the first transistor and the output node of the final gain stage.

(2) The amplifier circuit according to (1), wherein
a gain from the gate or the base of the first transistor to the output node of the final gain stage has a negative polarity when a DC signal is input to the gate or the base of the first transistor.

(3) The amplifier circuit according to (1) or (2), wherein
the active load includes a current mirror circuit including the first transistor and a second transistor, and
the second resistor is connected between the gate or the base of the first transistor and a gate or a base of the second transistor.

(4) The amplifier circuit according to (1) or (2), wherein
the second resistor has:
   one end connected to the gate or the base of the first transistor; and
   another end to which a predetermined bias voltage is supplied.

(5) The amplifier circuit according to any one of (1) to (4), wherein
a product of a transconductance value of the first transistor and a resistance value of the second resistor is 1 or more.

(6) The amplifier circuit according to any one of (1) to (5), wherein
each of the plurality of gain stages includes a common-source amplifier circuit or a common-emitter amplifier circuit.

(7) The amplifier circuit according to any one of (1) to (6), wherein
the first gain stage includes a differential circuit.

(8) The amplifier circuit according to any one of (1) to (7), comprising
a positive input terminal to which a signal having a phase opposite to a phase of a signal input to the negative input terminal is input, wherein
the first gain stage includes:
   a first differential circuit to which the negative input terminal and the positive input terminal are connected; and
   a second differential circuit to which the negative input terminal and the positive input terminal are connected, and
the capacitor includes:
   a first capacitor connected between an active load of the first differential circuit and an output node of the final gain stage; and
   a second capacitor connected between an active load of the second differential circuit and the output node of the final gain stage.

(9) An amplifier circuit comprising:
a plurality of gain stages that change a gain in each stage and include a first gain stage, a second gain stage, and a final gain stage;
an output terminal that outputs a signal amplified by the first gain stage and the final gain stage;
a negative input terminal connected to an input node of the first gain stage;
a feedback circuit connected between an output node of the final gain stage and the negative input terminal;
a first resistor connected between the output node of the final gain stage and the output terminal; and
a capacitor and the second gain stage connected in series to a path from the output node of the final gain stage to an input node of the final gain stage.

(10) The amplifier circuit according to (9), wherein
a gain of the second gain stage is larger than 1.

(11) The amplifier circuit according to (9) or (10), wherein
the second gain stage includes a common-source amplifier circuit or a common-emitter amplifier circuit.

(12) The amplifier circuit according to any one of (1) to (11), comprising
a switching circuit that performs selection for connecting the output node of the final gain stage to any one of a plurality of load circuits, wherein
the first resistor includes an on-resistor of the switching circuit.

(13) The amplifier circuit according to any one of (1) to (12), wherein
the feedback circuit has wiring and has no active element and no passive element, and
the amplifier circuit operates as a voltage follower circuit.

(14) A photodetection device comprising :
a plurality of pixels each having a photoelectric conversion element that converts an optical signal into an electrical signal; and
a voltage buffer that supplies a predetermined voltage to one end of the photoelectric conversion element, wherein
the voltage buffer includes the amplifier circuit according to any one of (1) to (13).

(15) The photodetection device according to (14), wherein
a gain from the gate or the base of the first transistor to the output node of the final gain stage has a negative polarity when a DC signal is input to the gate or the base of the first transistor.

(16) The photodetection device according to (14) or (15), wherein
the active load includes a current mirror circuit including the first transistor and a second transistor, and
the second resistor is connected between the gate or the base of the first transistor and a gate or a base of the second transistor.

(17) The photodetection device according to (14) or (15), wherein
the second resistor has:
   one end connected to the gate or the base of the first transistor; and
   another end to which a predetermined bias voltage is supplied.

(18) The photodetection device according to any one of (14) to (17), wherein
a product of a transconductance value of the first transistor and a resistance value of the second resistor is 1 or more.

(19) A photodetection device comprising:
a plurality of pixels each having a photoelectric conversion element that converts an optical signal into an electrical signal; and
a voltage buffer that supplies a predetermined voltage to one end of the photoelectric conversion element, wherein
the voltage buffer includes the amplifier circuit according to any one of (9) to (11).

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. An amplifier circuit comprising:
a plurality of gain stages that change a gain in each stage and include a first gain stage and a final gain stage;
an output terminal that outputs a signal amplified by the plurality of gain stages;
a negative input terminal connected to an input node of the first gain stage;
a feedback circuit connected between an output node of the final gain stage and the negative input terminal;
a first resistor connected between the output node of the final gain stage and the output terminal;
an active load of the first gain stage including a first transistor;
a second resistor connected to a gate or a base of the first transistor; and
a capacitor connected between the gate or the base of the first transistor and the output node of the final gain stage.

2. The amplifier circuit according to claim 1, wherein
a gain from the gate or the base of the first transistor to the output node of the final gain stage has a negative polarity when a DC signal is input to the gate or the base of the first transistor.

3. The amplifier circuit according to claim 1, wherein
the active load includes a current mirror circuit including the first transistor and a second transistor, and
the second resistor is connected between the gate or the base of the first transistor and a gate or a base of the second transistor.

4. The amplifier circuit according to claim 1, wherein
the second resistor has:
one end connected to the gate or the base of the first transistor; and
another end to which a predetermined bias voltage is supplied.

5. The amplifier circuit according to claim 1, wherein
a product of a transconductance value of the first transistor and a resistance value of the second resistor is 1 or more.

6. The amplifier circuit according to claim 1, wherein
each of the plurality of gain stages includes a common-source amplifier circuit or a common-emitter amplifier circuit.

7. The amplifier circuit according to claim 1, wherein
the first gain stage includes a differential circuit.

8. The amplifier circuit according to claim 1, comprising
a positive input terminal to which a signal having a phase opposite to a phase of a signal input to the negative input terminal is input, wherein
the first gain stage includes:
a first differential circuit to which the negative input terminal and the positive input terminal are connected; and
a second differential circuit to which the negative input terminal and the positive input terminal are connected, and
the capacitor includes:
a first capacitor connected between an active load of the first differential circuit and an output node of the final gain stage; and
a second capacitor connected between an active load of the second differential circuit and the output node of the final gain stage.

9. An amplifier circuit comprising:
a plurality of gain stages that change a gain in each stage and include a first gain stage, a second gain stage, and a final gain stage;
an output terminal that outputs a signal amplified by the first gain stage and the final gain stage;
a negative input terminal connected to an input node of the first gain stage;
a feedback circuit connected between an output node of the final gain stage and the negative input terminal;
a first resistor connected between the output node of the final gain stage and the output terminal; and
a capacitor and the second gain stage connected in series to a path from the output node of the final gain stage to an input node of the final gain stage.

10. The amplifier circuit according to claim 9, wherein
a gain of the second gain stage is larger than 1.

11. The amplifier circuit according to claim 9, wherein
the second gain stage includes a common-source amplifier circuit or a common-emitter amplifier circuit.

12. The amplifier circuit according to claim 1, comprising
a switching circuit that performs selection for connecting the output node of the final gain stage to any one of a plurality of load circuits, wherein
the first resistor includes an on-resistor of the switching circuit.

13. The amplifier circuit according to claim 1, wherein
the feedback circuit has wiring and has no active element and no passive element, and
the amplifier circuit operates as a voltage follower circuit.

14. A photodetection device comprising :
a plurality of pixels each having a photoelectric conversion element that converts an optical signal into an electrical signal; and
a voltage buffer that supplies a predetermined voltage to one end of the photoelectric conversion element, wherein
the voltage buffer includes the amplifier circuit according to claim 1.

15. The photodetection device according to claim 14, wherein
a gain from the gate or the base of the first transistor to the output node of the final gain stage has a negative polarity when a DC signal is input to the gate or the base of the first transistor.

16. The photodetection device according to claim 14, wherein
the active load includes a current mirror circuit including the first transistor and a second transistor, and
the second resistor is connected between the gate or the base of the first transistor and a gate or a base of the second transistor.

17. The photodetection device according to claim 14, wherein
the second resistor has:
one end connected to the gate or the base of the first transistor; and
another end to which a predetermined bias voltage is supplied.

18. The photodetection device according to claim 14, wherein
a product of a transconductance value of the first transistor and a resistance value of the second resistor is 1 or more.

19. A photodetection device comprising:
a plurality of pixels each having a photoelectric conversion element that converts an optical signal into an electrical signal; and
a voltage buffer that supplies a predetermined voltage to one end of the photoelectric conversion element, wherein
the voltage buffer includes the amplifier circuit according to claim 9.
